(19) United States
(12) Patent Application Publication
(10) Pub. No.: US 2025/0336467 A1
(43) Pub. Date: Oct. 30, 2025

(54) ADDRESS TRANSLATION CIRCUIT AND MEMORY

(71) Applicant: CXMT Corporation, Hefei (CN)

(72) Inventor: Lai Jiang, Hefei (CN)

(73) Assignee: CXMT Corporation, Hefei (CN)

(21) Appl. No.: 19/238,517

(22) Filed: Jun. 15, 2025

Related U.S. Application Data
(63) Continuation of application No. PCT/CN2024/093306, filed on May 15, 2024.

(30) Foreign Application Priority Data
Dec. 29, 2023 (CN) 202311872867.1

(51) Int. Cl. G11C 29/52; G11C 11/4076; G11C 29/00

(52) U.S. Cl. CPC G11C 29/52; G11C 11/4076; G11C 29/76

(57) ABSTRACT

A address translation circuit includes: a frequency division circuit, configured to receive a first address increment signal with a first frequency, process the first address increment signal, and output a second address increment signal with a second frequency as well as a jump signal with the second frequency, where the jump signal is used to indicate a first address jumping among the N memory banks; an address counter, configured to receive the second address increment signal and output an address count signal; and a row address increment circuit, configured to output a first row address increment signal when the address count signal indicates that column address counting has been finished, and the jump signal indicates a last memory bank group.

### CROSS-REFERENCE TO RELATED APPLICATIONS

This is a continuation application of International Application No. PCT/CN2024/093306 filed on May 15, 2024, which claims priority to Chinese Patent Application No. 202311872867.1 filed on Dec. 29, 2023. The disclosures of the above-referenced applications are hereby incorporated by reference in their entirety.

### TECHNICAL FIELD

Embodiments of the present disclosure relate to the technical field of semiconductors, and relate to but are not limited to an address translation circuit and a memory.

### BACKGROUND

During the use of memory, data read and write errors often occur due to process deviations in memory cells or circuits. These errors cannot be completely avoided, but they can be mitigated through certain detection and error correction methods to ensure the normal operation of the memory. Therefore, a memory is provided with circuits related to detection and error correction, such as Error Check and Scrub (Error Check and Scrub, ECS) and Error Checking and Correction (Error Checking and Correction, ECC), to achieve detection and error correction of data read/write units within the memory. To reduce the space occupied by circuits related to detection and error correction, the aforementioned circuits can often simultaneously test a plurality of memory banks (BK, Bank) or a plurality of memory bank groups (BG, Bank Group). However, in such cases, it is often difficult for the error-related addresses detected to match with the actual addresses, which leads to issues such as incomplete detection data.

### SUMMARY

According to a first aspect of the embodiments of the present disclosure, an address translation circuit is provided. The address translation circuit is applicable to a memory, the memory includes N memory bank groups, and the address translation circuit includes:
a frequency division circuit, configured to receive a first address increment signal with a first frequency, process the first address increment signal, and output a second address increment signal with a second frequency as well as a jump signal with the second frequency, where the first address increment signal is used to indicate address incrementation when the memory is in a first configuration, and the second address increment signal is used to indicate address incrementation when the memory is in a second configuration; the jump signal is used to indicate an address jumping among the N memory bank groups; the first frequency is N times the second frequency, and N is a positive integer greater than 1;
an address counter, configured to receive the second address increment signal and output an address count signal; and
a row address increment circuit, coupled to the address counter and the frequency division circuit and configured to output a first row address increment signal when the address count signal indicates that column address counting has been finished, and the jump signal indicates a last memory bank group.

In some embodiments, the frequency division circuit includes: a first flip-flop, where a clock input terminal of the first flip-flop is configured to receive the first address increment signal, and an output terminal of the first flip-flop is connected to a data input terminal and outputs the jump signal; and a first processing unit, where a first input terminal of the first processing unit is coupled to the output terminal of the first flip-flop, and a second input terminal of the first processing unit receives the first address increment signal; an output terminal of the first processing unit outputs the second address increment signal.

In some embodiments, the frequency division circuit further includes: a first AND gate. A first input terminal of the first AND gate receives a second configuration signal, and a second input terminal of the first AND gate receives an initial reset signal; an output terminal of the first AND gate outputs a reset signal; a reset terminal of the first flip-flop receives the reset signal.

In some embodiments, the address counter includes: M counting units, where output terminals of the M counting units at all stages are respectively configured to output a count value of one bit of an address, and M is an integer greater than 2; M−1 second AND gates, where a first input terminal of each of the M−1 second AND gates is connected to an output terminal of one of the M counting units, and a second input terminal of each of the M−1 second AND gates is connected to an output terminal of a previous-stage counting unit or an output terminal of a preceding second AND gate; and M−1 XOR gates, where a first input terminal of each of the M−1 XOR gates is connected to an output terminal of one of the M counting units or an output terminal of one of the M−1 second AND gates, and a second input terminal of each of the M−1 XOR gates is connected to an output terminal of a subsequent-stage counting unit.

In some embodiments, each of the M counting units includes: a second flip-flop; the M counting units comprises: a first counting unit, a second counting unit, . . . , a (i+1)-th counting unit, . . . , wherein i is an integer greater than 1 and less than M.

An output terminal of a second flip-flop in the first counting unit is connected to a data input terminal of the second flip-flop in the first counting unit.

A first input terminal of a first XOR gate is connected to the output terminal of the second flip-flop in the first counting unit, and a second input terminal of the first XOR gate is connected to an output terminal of the second flip-flop in the first counting unit.

A first input terminal of an i-th XOR gate is connected to an output terminal of an (i−1)-th second AND gate, and a second input terminal of the i-th XOR gate is connected to an output terminal of the second flip-flop in the (i+1)-th counting unit.

In some embodiments, a first input terminal of a first second AND gate is connected to the output terminal of the second flip-flop in the second counting unit, and a second input terminal of the first second AND gate is connected to the output terminal of the second flip-flop in the first counting unit.

A first input terminal of a j-th second AND gate is connected to an output terminal of a second flip-flop in the (j+1)-th counting unit, and a second input terminal of the j-th second AND gate is connected to an output terminal of a (j−1)-th second AND gate, where j is an integer greater than 1 and less than M.

In some embodiments, the address counter further includes: a third AND gate.

A first input terminal of the third AND gate is coupled to the frequency division circuit and configured to receive the jump signal, and a second input terminal of the third AND gate is connected to an output terminal of an (M−2)-th second AND gate; an output terminal of the third AND gate is configured to output a stop signal, the stop signal indicating that address counting has been finished.

In some embodiments, the address counter further includes: a first signal selector, where a first input terminal of the first signal selector is connected to an output terminal of an M-th second flip-flop in the address counter, and a second input terminal of the first signal selector is connected to an output terminal of the frequency division circuit and configured to receive the jump signal; a control terminal of the first signal selector is configured to receive a mode selection signal, and an output terminal of the first signal selector is connected to the first input terminal of the third AND gate; the mode selection signal is used to indicate whether the memory is in the first configuration or the second configuration.

In some embodiments, the row address increment circuit includes: a fourth AND gate, where a first input terminal of the fourth AND gate is connected to the address counter and configured to receive a second row address increment signal, and a second input terminal of the fourth AND gate is connected to an output terminal of the frequency division circuit and configured to receive the jump signal; an output terminal of the fourth AND gate outputs the first row address increment signal, where the second row address increment signal is used to indicate that the column address counting has been finished.

In some embodiments, the row address increment circuit further includes: a second signal selector, where a first input terminal of the second signal selector is connected to the address counter and configured to receive the second row address increment signal, and a second input terminal of the second signal selector is connected to the output terminal of the fourth AND gate; a signal selection terminal of the second signal selector is configured to receive a mode selection signal, where when the mode selection signal indicates that the memory is in the first configuration, the second signal selector outputs the second row address increment signal; when the mode selection signal indicates that the memory is in the second configuration, the second signal selector outputs the first row address increment signal.

In some embodiments, the address translation circuit further includes: a third signal selector, where a first input terminal of the third signal selector is configured to receive the first address increment signal, and a second input terminal of the third signal selector is connected to an output terminal of the frequency division circuit and configured to receive the second address increment signal; an output terminal of the third signal selector is connected to a clock input terminal of the address counter, and a signal selection terminal of the third signal selector is configured to receive a mode selection signal.

When the mode selection signal indicates that the memory is in the first configuration, the third signal selector outputs the first address increment signal; when the mode selection signal indicates that the memory is in the second configuration, the third signal selector outputs the second address increment signal.

In some embodiments, a duty cycle of the jump signal is 1/N.

In some embodiments, the first configuration corresponds to an X8 mode of the memory, and the second configuration corresponds to an X16 mode of the memory.

In some embodiments, the first processing unit includes a NOR gate that receives the first address increment signal and the jump signal and generates the second address increment signal.

According to a second aspect of the embodiments of the present disclosure, a memory is provided. The memory includes: N memory bank groups and the address translation circuit according to any one of the above embodiments. The N memory bank groups perform an ECS operation according to a first row address increment signal and a stop signal output by the address translation circuit.

### BRIEF DESCRIPTION OF DRAWINGS

FIG. 1 is a schematic diagram of an ECS according to an embodiment of the present disclosure;

FIG. 2 is a read/write timing diagram of an ECS operation according to an embodiment of the present disclosure;

FIG. 3 is a signal waveform diagram of error counting in row mode during an ECS operation according to an embodiment of the present disclosure;

FIG. 4 is a signal waveform diagram of a maximum error counting mode during an ECS operation according to an embodiment of the present disclosure;

FIG. 5 is a schematic diagram of an address translation circuit according to an embodiment of the present disclosure;

FIG. 6 is a schematic signal waveform diagram of an address translation circuit according to an embodiment of the present disclosure;

FIG. 7 is a schematic structural diagram of a frequency division circuit in an address translation circuit according to an embodiment of the present disclosure;

FIG. 8 is a schematic diagram of a partial structure of an address translation circuit according to an embodiment of the present disclosure; and

FIG. 9 is a schematic diagram of a partial structure of another address translation circuit according to an embodiment of the present disclosure.

FIG. 10 is a schematic diagram of a memory structure according to an embodiment of the present disclosure.

### DESCRIPTION OF EMBODIMENTS

To facilitate understanding of the present disclosure, a more comprehensive description of the present disclosure will be provided hereinafter with reference to the relevant drawings. The drawings illustrate preferred embodiments of the present disclosure. However, the present disclosure can be implemented in a variety of different forms and is not limited to the embodiments described herein. Rather, these embodiments are provided to make the disclosed content of the present disclosure more thorough and comprehensive.

Unless otherwise defined, all technical and scientific terms used herein have the same meaning as commonly understood by those skilled in the art to which the present disclosure belongs. The terms used in the specification of the present disclosure are for the purpose of describing particular embodiments only and are not intended to limit the present disclosure. The term “and/or” as used herein includes any and all combinations of one or more related listed items.

The memory in the embodiments of the present disclosure includes, but is not limited to, Dynamic Random Access Memory (Dynamic Random Access Memory, DRAM), Static Random Access Memory (Static Random Access Memory, SRAM), Ferroelectric Random Access Memory (Ferroelectric Random Access Memory, FRAM), Magneto resistive Random Access Memory (Magneto resistive Random Access Memory, MRAM), Phase Change Random Access Memory (Phase Change Random Access Memory, PCRAM), Resistive Random Access Memory (Resistive Random Access Memory, RRAM), Nano Random Access Memory (Nano Random Access Memory, NRAM), etc.

Taking DRAM as an example, the peripheral circuitry thereof includes an ECS module. The function of ECS is roughly as follows: ECS generates a read/write command through self-timing. During this process, data is not read out but rather undergoes internal error correction and is then written back. If there is an error signal, the error signal is transmitted to an error counter for counting.

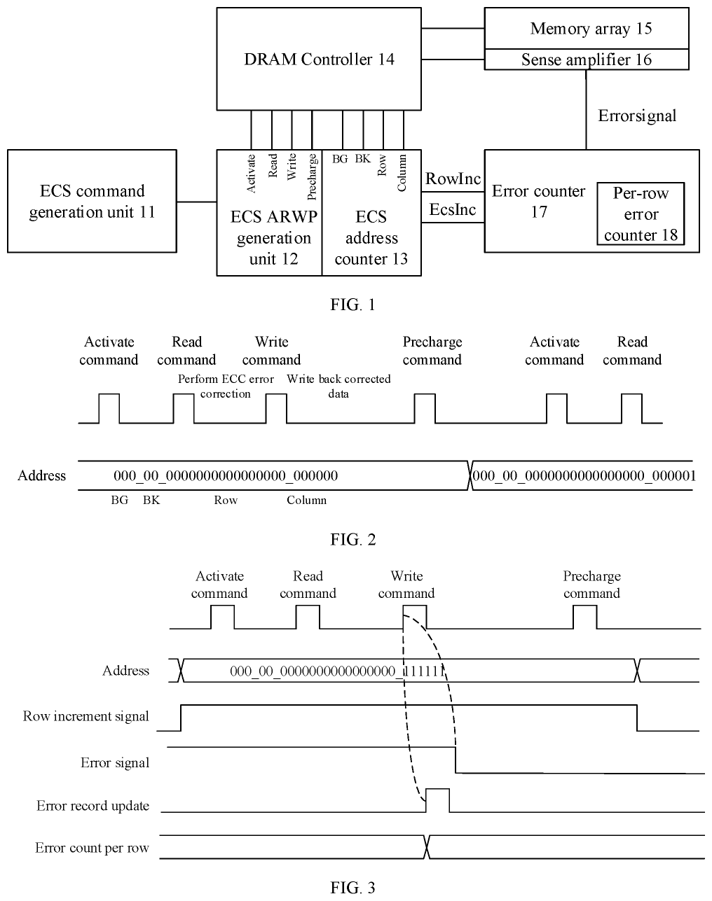

The schematic diagram of ECS is shown in FIG. 1. An ECS command generation unit 11 generates an ECS command, an ECS ARWP (Active Read Write Precharge, Active-Read-Write-Precharge command) generation unit 12 generates a related command, and an ECS address counter 13 performs address counting. The aforementioned ARWP command and an address count value are transmitted to a memory array 15 through a DRAM controller 14. The sense amplifier 16 within the memory array 15 performs read and write operations on the memory cells. When an error is detected, an error signal is generated and transmitted to an error counter 17, enabling the counting of the number of errors. In addition, the error counter 17 further includes a per-row error counter 18, which is configured to count errors in each row. The error counter 17 is connected to the ECS address counter 13, such that a row increment signal RowInc and an ECS end signal EcsInc can be obtained. The per-row error counter 18 can be cleared to zero each time a row increment signal RowInc is detected and then begin counting for a new row. When the error counter 17 detects the ECS end signal EcsInc, it indicates that all addresses have been scanned, thus marking the end of the ECS operation and stopping the counting process.

The read/write timing for the ECS operation is shown in FIG. 2. An ECS is performed each time the address is updated, thereby scanning each memory cell once. The scanning continues until all bits of the address are “1”, which indicates the end of the scan. At this point, the ECS end signal EcsInc is received, and the ECS stops.

The waveform for recording the number of errors in ECS row mode is shown in FIG. 3. During the column address update process, if an error occurs, an error signal will be generated along with the write command, and an error record update pulse will be generated to record the error count for the current row. When all bits of the column address are “1”, the scan for the current row is completed, and a row increment signal is generated accordingly. At this point, the error count represents the total number of errors in the scanned row.

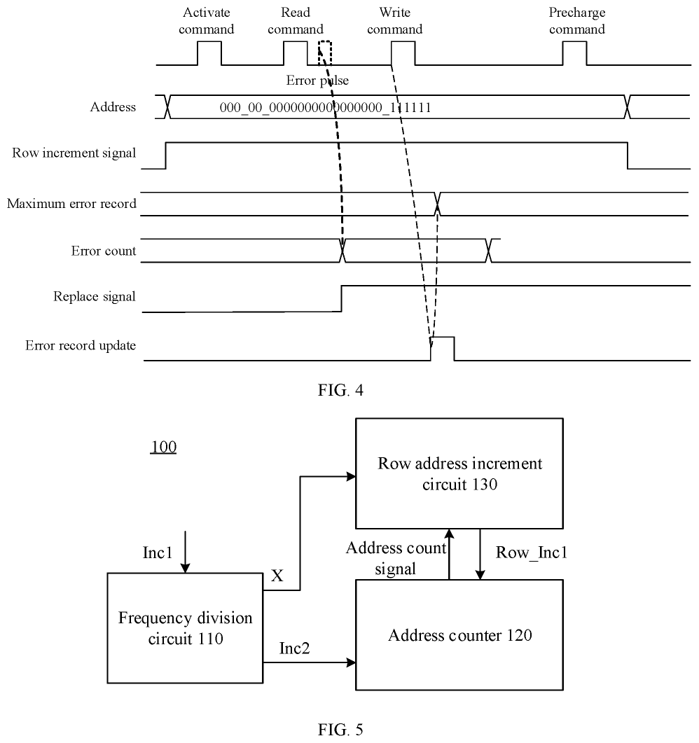

The waveform for the ECS maximum error count mode is shown in FIG. 4. The maximum error record contains the address and the number of errors of the row with the highest number of errors among all previously scanned rows. During the scanning of the current row, if an error is detected, an error pulse is generated to update the error count. When all bits of the column address are “1”, the scan of the current row is completed, and a row increment signal is generated accordingly. At this point, the error count represents the number of errors in the current row. After the scan of one row is completed, the error count of the current row can be compared with the error count in the maximum error record. If the error count of the current row is greater, an error record update pulse is generated. Moreover, in the case where the replace signal is at a high level, the maximum error record is updated based on the rising edge of the error record update pulse.

It should be noted that the address counter used in the above-mentioned ECS is an address counter in X8 mode. If the ECS operation is performed in X16 mode, two BGs are merged, such that the length of each row is doubled. Therefore, if the actual address needs to be recorded, the number of bits in the column address needs to be doubled. However, the structure of the address counter is fixed, making it impossible to actually achieve address recording in X16 mode. This results in a mismatch between the ECS recorded address in X16 mode and the actual address, making it impossible to accurately record information such as the row with the maximum errors and the maximum number of errors.

Those skilled in the art can understand that the X16 mode refers to a mode in which all 16 input/output terminals of the memory are used for data output. The 16 input/output terminals can transmit data in parallel. Correspondingly, the input/output terminals include the lower eight bits of the LDQ (Low Data Queue, low-order data queue) and the upper eight bits of the UDQ (Up Data Queue, high-order data queue). The X8 mode refers to a mode in which eight input/output terminals are used for data output, that is, only the lower eight bits of LDQ are used. For example, in X16 mode, a DRAM includes four BGs, with each BG including four BKs, and a page size of 2 KB; in X8 mode, the DRAM includes eight BGs, with each BG including four BKs, and a page size of 1 KB. Therefore, the length of a row (i.e., the number of column address bits) in X16 mode is twice that in X8 mode.

The embodiment of the present disclosure provides an address translation circuit, which is applicable to a memory. The memory includes N memory bank groups, as shown in FIG. 5. The address translation circuit 100 includes the following elements.

A frequency division circuit 110 is included. The frequency division circuit is configured to receive a first address increment signal Inc1 with a first frequency, process the first address increment signal, and output a second address increment signal Inc2 with a second frequency as well as a jump signal X with the second frequency. The first address increment signal Inc1 is used to indicate address incrementation when the memory is in a first configuration, and the second address increment signal Inc2 is used to indicate address incrementation when the memory is in a second configuration. The jump signal X is used to indicate an address jumping among the N memory bank groups. The first frequency is N times the second frequency, where N is a positive integer greater than 1.

An address counter 120 is included. The address counter is configured to receive the second address increment signal Inc2 and output an address count signal.

A row address increment circuit 130 is included. The row address increment circuit is coupled to the address counter 120 and the frequency division circuit 110 and configured to output a first row address increment signal Row_Inc1 when the address count signal indicates that the column address counting has been finished, and the jump signal X indicates the last memory bank group.

In the embodiment of the present disclosure, the count value of the address counter 120 represents the address value. The address here may include the individual bit values of the column address CA, the row address RA, the bank address BK, and the memory bank group address BG. The function of the address counter 120 is to perform counting based on the input second address increment signal Inc2. With each count, the next address is outputted. For example, if the lowest-order bit of the address counter represents the column address, then each counting is equivalent to incrementing the column address by 1.

It can be understood that the address counter 120 includes a multi-bit output terminal for outputting the value of each address bit. One set of values output by the multi-bit output terminal at a time represents one complete address. In addition, if it is necessary to find the row address, column address, or other addresses of the current count, it can be directly acquired from the corresponding multi-bit output terminal of the address counter 120. For example, the column address includes six bits, the row address includes 16 bits, the memory bank address includes two bits, and the memory bank group address includes two bits (in the X8 mode, the memory bank group address includes three bits). To find the end of a column address corresponding to a row address, i.e., when all six bits of the column address are “1”, the next count will move to the next row. Therefore, the row address is incremented by 1, and the column address is cleared to zero. The address counter 120 may perform address counting using the first address increment signal Inc1 as the clock signal. In this case, the frequency of the address counting is the first frequency. When the address counter 120 performs address counting using the second address increment signal Inc2 as the clock signal, the frequency of the address counting is the second frequency.

In the embodiment of the present disclosure, the frequency division circuit 110 is used to generate the aforementioned second address increment signal Inc2 with the second frequency through frequency division. In addition, a jump signal X is generated through either frequency division or frequency multiplication processing.

The first frequency may be N times the second frequency, where N represents a positive integer greater than 1. For example, N may be 2, 4, etc. That is, the frequency division circuit 110 generates the second address increment signal Inc2 through frequency division, causing the address counter to jump more slowly. The purpose of this is to enable different memory bank groups BGs to be switched by utilizing the jumps of the jump signal X within one cycle of the second address increment signal.

In some embodiments, the duty cycle of the jump signal X is 1/N.

The frequency of the jump signal X is the same as that of the second address increment signal Inc2, and the duty cycle of the jump signal X represents the frequency of switching between different memory bank groups. The duty cycle is 1/N, where N may be an integer greater than 1. For example, when N is equal to 2, the duty cycle of the jump signal X is 0.5, i.e., 50%, and there are two jumps within one address counting cycle, thereby achieving the switching between two different BGs. When N is equal to 4, the duty cycle of the jump signal X is 0.25, i.e., 25%, and there are four jumps within one address counting cycle, thereby achieving the switching between four different BGs.

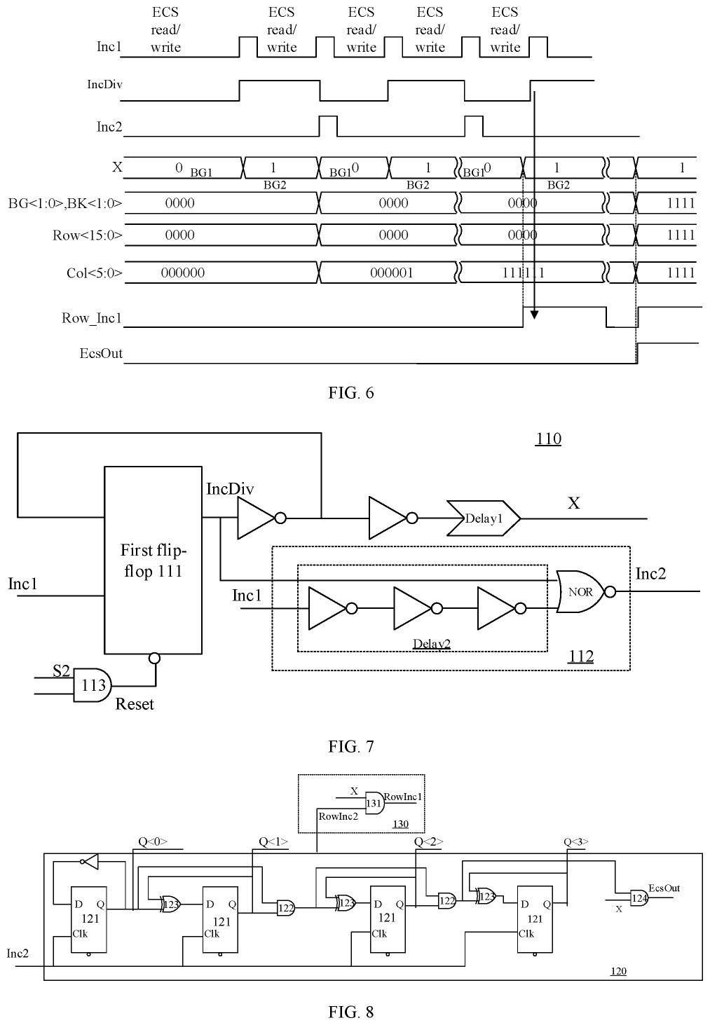

Referring to FIG. 6, an ECS read/write operation is performed sequentially during each cycle of the first address increment signal Inc1. The aforementioned frequency division circuit 110 can perform frequency division on the first address increment signal Inc1 to obtain a frequency division signal IncDiv and, based on the frequency division signal IncDiv, generate the jump signal X and the second address increment signal Inc2. The address counter 120 performs counting for each address bit. For example, as shown in FIG. 6, these address bits are represented as the four-bit memory bank group and memory bank number BG<1:0>, BK<1:0>, the sixteen-bit row address Row<15:0>, and the six-bit column address Col<5:0>. The first row address increment signal Row_Inc1 indicates a row address carry when all column address bits are 1, and the jump signal X is 1. The end signal EcsOut indicates that all address counting has been completed, and the jump signal X has finished jumping.

For example, as shown in FIG. 6, the first frequency is twice the second frequency, and the duty cycle of the jump signal X is 0.5. The jump signal X transitions between “0” and “1”. For example, when the jump signal X is “0”, it indicates the first memory bank group BG1, and when the jump signal X is “1”, it indicates the second memory bank group BG2. The ECS circuit may perform an ECS read/write operation based on the first address increment signal Inc1, but the address counter performs counting by using the second address increment signal Inc2 as the clock. Under one address, two different BGs are actually switched, and an ECS read/write operation is performed separately on the memory cells at the same address in the two different BGs.

In addition, the address counter 120 performs column address counting sequentially within each row. After column address counting for one row is completed, the address counter performs a carry operation on the row address based on the row address increment signal, clears the column address count to zero, and thereby proceeds to the next row for counting.

Because the number of address bits included in each row is doubled in the second configuration, and the jump signal X performs jumping between different BGs for each column address based on the original column address counting, the aforementioned row address increment signal cannot be determined as requiring a carry to the next row simply based on all bit counts of the column address in the address counter 120 being “1”. It is also necessary to ensure that when the final column address, i.e., all bits of the column address, are “1”, the jump signal X also jumps to the final BG. Only then can the column address counting for one row be considered complete, thereby outputting the row address increment signal. Therefore, in the embodiment of the present disclosure, the aforementioned row address increment circuit 130 outputs the first row address increment signal Row_Inc1 only when the address count signal indicates the end of column address counting and the jump signal X indicates the final memory bank group. In this case, the signal may be used to indicate clearing the current column address count to zero and carrying the row address.

The aforementioned first configuration represents a configuration mode where complete address counting can be achieved solely by using the first address increment signal Inc1. The second configuration represents a configuration mode where complete address counting can be achieved by using the second address increment signal Inc2 in conjunction with the jump signal X. For example, the first configuration corresponds to the X8 mode of the memory, and the second configuration corresponds to the X16 mode of the memory.

In this way, without altering the related circuitry of address counting, merely by adjusting the frequency of address counting and adding a jump signal X, the extension of address counting is achieved. Compared to doubling the number of bits of two column addresses, the solution of the embodiment of the present disclosure enables counting larger-scale addresses in the second configuration without requiring large-scale circuit modifications, while maintaining compatibility with the first configuration.

In some embodiments, as shown in FIG. 7, the frequency division circuit 110 includes the following elements.

A first flip-flop 111 is included. A clock input terminal of the first flip-flop is configured to receive the first address increment signal Inc1, and an output terminal of the first flip-flop is connected to a data input terminal and outputs the jump signal X.

A first processing unit 112 is included. A first input terminal of the first processing unit is coupled to the output terminal of the first flip-flop 111, and a second input terminal of the first processing unit receives the first address increment signal Inc1; an output terminal of the first processing unit outputs the second address increment signal Inc2.

The first flip-flop 111 performs frequency division processing by using the first address increment signal Inc1 as the clock and outputs the frequency division signal IncDiv as shown in FIG. 6. The output terminal of the first flip-flop is connected to the data input terminal, or the inverted output terminal is connected to the aforementioned data input terminal, and the frequency division signal may be used as the aforementioned jump signal X. Moreover, after processing the output signal by the first processing unit 112, the corresponding second address increment signal Inc2 is generated. That is, the second frequency of the second address increment signal Inc2 is also obtained through the frequency division processing performed by the first flip-flop 111.

For example, the first processing unit 112 may include one NOR gate, and the input signals thereof are the aforementioned first address increment signal Inc1 and the aforementioned jump signal X. In this way, the waveform of the second address increment signal Inc2 as shown in FIG. 6 can be generated.

Here, to align the signal waveforms of the jump signal X and the second address increment signal Inc2, the aforementioned frequency division circuit 110 may further include a first delay unit Delay1 for delaying the jump signal X, as well as a second delay unit Delay2 for delaying the second address increment signal Inc2. The first/second delay units may include structures such as several inverters.

In some embodiments, as shown in FIG. 7, the frequency division circuit 110 further includes a first AND gate 113. A first input terminal of the first AND gate 113 receives the configuration signal S2 that is used to indicate the second configuration, and a second input terminal of the first AND gate receives the initial reset signal; an output terminal of the first AND gate outputs the reset signal Reset. A reset terminal of the first flip-flop receives the reset signal Reset.

Here, the first AND gate 113 ensures that the reset terminal of the first flip-flop 111 is only reset upon receiving the reset signal Reset in the case where the memory is in the second configuration. That is, the frequency division circuit 110 is used in the second configuration, and may not be used in the first configuration.

In some embodiments, as shown in FIG. 8, the address counter 120 includes the following elements.

M counting units 121 are included. Output terminals of the counting units 121 at all stages are respectively configured to output the count value Q of one bit of the address. M is an integer greater than 2.

M−1 second AND gates 122 are included. A first input terminal of each second AND gate 122 is connected to the output terminal of one counting unit 121, and a second input terminal of each second AND gate is connected to the output terminal of the previous-stage counting unit 121 or the output terminal of the preceding second AND gate 122.

M−1 XOR gates 123 are included. A first input terminal of each XOR gate 123 is connected to the output terminal of one counting unit 121 or the output terminal of one second AND gate 122, and a second input terminal of each XOR gate is connected to the output terminal of the subsequent-stage counting unit 121.

Each counting unit 121 outputs a one-bit count value Q<x>, i.e., the x-th bit of the aforementioned address count value. For example, the last count value represents the last column address bit, and the first count value represents the BG address bit, and so on. For example, the address counter 120 includes: 6 bits for the column address, 16 bits for the row address, 2 bits for the memory bank address, and 3 bits for the memory bank group address, totaling 27 bits. Thus, the address counter 120 includes 27 counting units 121, 26 second AND gates 122, and 26 XOR gates 123. It should be noted that the memory bank group address here is of three bits, and three counting units 121 are required to be compatible with the address counter 120 in the X8 configuration. In the X16 configuration, the memory bank group address only needs two bits. (FIG. 8 uses 4 bits as an example.)

The function of the XOR gate 123 is to connect the counting units 121 of each stage, enabling the carrying for counting. The function of the second AND gate 122 is to determine whether the counting at each stage connected thereto has been finished. The second AND gate 122 outputs “1” only when all connected count values are “1”, thus indicating that the counting for the connected bits has been finished.

It can be understood that if a second AND gate 122 is connected to the output terminals of two counting units 121, then the output of the second AND gate indicates that the counting for the two bits has been finished. If the second AND gate is connected to the output terminal of one counting unit 121 and the output terminal of another second AND gate 122, then the output of the second AND gate indicates that all the counting units 121 connected to the two second AND gates 122 have finished counting. Thus, if a plurality of second AND gates 122 are connected sequentially, then the output result of the last second AND gate 122 can be used to determine whether all the counting units 121 connected to the plurality of second AND gates have finished counting.

Therefore, the output result of the second AND gates 122 with different connection relationships can be used to obtain the result of whether the counting within the corresponding number of address bits has been finished. This facilitates the separate determination of whether each part in the address counter 120, such as the bits representing the “column address” and the bits representing the “row address”, has finished counting. Additionally, all counting units 121 may be sequentially connected through second AND gates 122 to determine whether the entire address counting has been finished.

In some embodiments, as shown in FIG. 8, the counting unit 121 includes a second flip-flop.

An output terminal of a second flip-flop in the first counting unit is connected to a data input terminal of the second flip-flop in the first counting unit. Alternatively, an inverter may be connected between the output terminal of the first flip-flop and the data input terminal of the second flip-flop in the first counting unit.

In some embodiments, a first input terminal of the first XOR gate 123 is connected to the output terminal of the second flip-flop in the first counting unit, and a second input terminal of the first XOR gate is connected to the output terminal of a second flip-flop in the second counting unit.

A first input terminal of the i-th XOR gate 123 is connected to the output terminal of the (i−1)-th second AND gate 122, and a second input terminal of the i-th XOR gate is connected to the output terminal of a second flip-flop in the (i+1)-th counting unit, where i is an integer greater than 1 and less than M.

That is, except for the first XOR gate 123, each of the other XOR gates 123 is configured to perform an XOR operation between the output result of one counting unit 121 and the result of whether each of the previous-stage counting units 121 has finished counting (i.e., the output result of the second AND gate 122).

When the output result of the second AND gate 122 connected to the XOR gate 123 is “1” (the previous-stage counting has been finished) and the output result of the counting unit 121 connected to the XOR gate 123 is “0”, it indicates that the counting unit 121 needs to be incremented by 1 at this point. In this case, the XOR gate 123 outputs “1” to the counting unit 121, causing the next output result to transition to “1”.

When the output result of the second AND gate 122 connected to the XOR gate 123 is “1” (the previous-stage counting has been finished) and the output result of the counting unit 121 connected to the XOR gate 123 is “1”, it indicates that a carry is required. The counting unit 121 needs to be incremented by 1 and transition to “0” at this point. In this case, the XOR gate 123 outputs “0” to the counting unit 121, causing the next output result to transition to “0”.

When the output result of the second AND gate 122 connected to the XOR gate 123 is “0” (the previous-stage counting has not finished) and the output result of the counting unit 121 connected to the XOR gate 123 is “1”, the next counting unit 121 does not need to change and needs to wait for the transition from the previous stage. In this case, the XOR result is “1”, and the next counting result remains “1”.

When the output result of the second AND gate 122 connected to the XOR gate 123 is “0” (the previous-stage counting has not finished) and the output result of the counting unit 121 connected to the XOR gate 123 is “0”, the next counting unit 121 does not need to change and needs to wait for the transition from the previous stage. In this case, the XOR result is “0”, and the next counting result remains “0”.

For the first XOR gate 123, the first input terminal thereof is connected to the output terminal of the first-stage counting unit 121. That is, it only needs to determine whether the count value of the counting unit 121 is “0” or “1” to determine whether the next-stage counting unit 121should maintain the count value or increment the count value by 1. In some embodiments, as shown in FIG. 8, a first input terminal of the first second AND gate 122 is connected to the output terminal of the second flip-flop in the second counting unit, and a second input terminal of the first second AND gate is connected to the output terminal of the second flip-flop in the first counting unit.

A first input terminal of the j-th second AND gate 122 is connected to the output terminal of a second flip-flop in the (j+1)-th counting unit, and a second input terminal of the j-th second AND gate is connected to the output terminal of the (j−1)-th second AND gate 122, where j is an integer greater than 1 and less than M.

The connection method of the second AND gates 122 is similar to that of the XOR gates. In this way, the input to each second AND gate 122 is the result of whether all previous-stage counting units 121 have finished counting, ANDed with the count value of the counting unit 121 connected to the second AND gate. Thus, whether the counting of all preceding stages of each counting unit 121 has been finished is sequentially recorded. It can be understood that the output result of the second AND gate 122 connected to the last counting unit 121 indicates whether the entire address counter 120 has finished counting.

In some embodiments, as shown in FIG. 8, the address counter further includes a third AND gate 124. A first input terminal of the third AND gate 124 is coupled to the frequency division circuit 110 and configured to receive the jump signal X, and a second input terminal of the third AND gate is connected to the output terminal of the (M−2)-th second AND gate 122; an output terminal of the third AND gate is configured to output the stop signal EcsOut. The stop signal EcsOut indicates that address counting has been finished.

The (M−2)-th second AND gate 122 is the penultimate second AND gate 122. When a first output terminal of this second AND gate 122 outputs “1”, it indicates that all address counting of the address counter 120 in the X16 configuration has been finished. However, in the last counting cycle, the jump signal X still needs to jump once more; that is, during the period when the second AND gate 122 outputs “1”, the jump signal X first outputs “0” and then outputs “1”. When the jump signal X represents “1”, it indicates that the last address counting of the second memory bank has been finished, that is, all address counting has been finished.

Therefore, the third AND gate 124 is configured to perform an AND operation between the output result of the penultimate second AND gate 122 and the jump signal X. Thus, when the output of the third AND gate is “1”, it indicates that all counting has been finished, which serves as the stop signal EcsOut to indicate that the address counting has been finished. In this way, when applied to ECS, this signal can be used to indicate the end of the ECS operation.

In some embodiments, as shown in FIG. 8, the row address increment circuit 130 includes the following elements.

A fourth AND gate 131 is included. A first input terminal of the fourth AND gate is connected to the address counter 120 and configured to receive a second row address increment signal Row_Inc2, and a second input terminal of the fourth AND gate is connected to the output terminal of the frequency division circuit 110 and configured to receive the jump signal X. An output terminal of the fourth AND gate outputs the first row address increment signal Row_Inc1. The second row address increment signal Row_Inc2 is used to indicate that the column address counting has been finished.

The second row address increment signal Row_Inc2 is a carry indication signal output when all column address counting in the address counter 120 itself is “1”. In the first configuration, this signal indicates that the counting of each column for the current row has been finished, whereas in the second configuration, the signal can only indicate that the column address counting in the address counter has been finished and cannot indicate that the column address counting of each BG has been finished.

Therefore, in the embodiment of the present disclosure, the fourth AND gate 131 is used to perform an AND operation between the second row address increment signal Row_Inc2 and the jump signal X. When both are “1”, it indicates that counting has reached the last column address of the last BG, after which it is permissible to carry over to the next row. As a result, the first row address increment signal Row_Inc1 is output, which is used to indicate that, in the second configuration, the counter switches to the next row for counting.

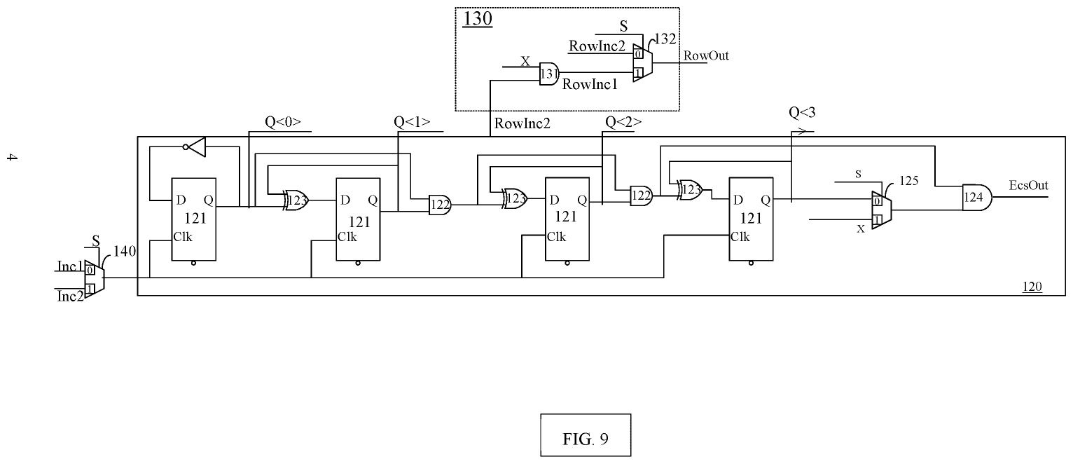

In some embodiments, as shown in FIG. 9, the address counter 120 further includes the following elements.

A first signal selector 125 is included. A first input terminal of the first signal selector is connected to the output terminal of a second flip-flop of the M-th counting unit in the address counter, and a second input terminal of the first signal selector is connected to the output terminal of the frequency division circuit 110 and configured to receive the jump signal X. A control terminal of the first signal selector is configured to receive the mode selection signal S, and an output terminal of the first signal selector is connected to the first input terminal of the third AND gate. The mode selection signal S is used to indicate whether the memory is in the first configuration or the second configuration.

In this way, when the mode selection signal S indicates the second configuration, the circuit shown in FIG. 9 is consistent with that in FIG. 8, that is, the third AND gate 124 outputs the stop signal only when the address counter 120 completes all the counting and the jump signal jumps to the last memory bank group.

When the mode selection signal S indicates the first configuration, the input signal of one input terminal of the third AND gate 124 is the output signal of the penultimate second AND gate 122, and the input signal of the other input terminal is the output signal of the last-stage counting unit 121, which indicates that the address counter has finished counting.

In this way, the output signal of the third AND gate 124 can be compatible with the first configuration and the second configuration, both serving to indicate whether the address counting has been finished.

In some embodiments, as shown in FIG. 9, the row address increment circuit 130 further includes the following elements.

A second signal selector 132 is included. A first input terminal of the second signal selector is connected to the address counter 120 and configured to receive the second row address increment signal Row_Inc2, and a second input terminal of the second signal selector is connected to the output terminal of the fourth AND gate 131. A signal selection terminal of the second signal selector is configured to receive the mode selection signal S. When the mode selection signal S indicates that the memory is in the first configuration, an output terminal RowOut of the second signal selector 132 outputs the second row address increment signal Row_Inc2. When the mode selection signal S indicates that the memory is in the second configuration, the second signal selector 132 outputs the first row address increment signal Row_Inc1.

In this way, the second signal selector 132 can be used to switch between the row address increment signals applicable to the first configuration and the second configuration, indicating that the column address counting for the current row has been finished and thus proceeding to the next row for counting.

It can be understood that when the memory is in the second configuration, the second row address increment signal Row_Inc2 cannot indicate the end of counting for a row of any memory bank, but can only indicate that the count value of each unit in the address counter used for column address counting is the maximum.

In this way, the use of the second signal selector 132 enables the row address increment circuit 130 to be compatible with both the first configuration and the second configuration.

In some embodiments, the address translation circuit 100 further includes the following elements.

A third signal selector 140 is included. A first input terminal of the third signal selector is configured to receive the first address increment signal Inc1, and a second input terminal of the third signal selector is connected to the output terminal of the frequency division circuit 110 and configured to receive the second address increment signal Inc2. An output terminal of the third signal selector is connected to the clock input terminal Clk of the address counter 120, and a signal selection terminal of the third signal selector is configured to receive the mode selection signal S.

When the mode selection signal S indicates that the memory is in the first configuration, the third signal selector 140 outputs the first address increment signal Incl. When the mode selection signal S indicates that the memory is in the second configuration, the third signal selector outputs the second address increment signal Inc2.

Similar to the first and second signal selectors, the third signal selector 140 is also configured to achieve the switching between the first configuration and the second configuration of the memory. When the first configuration is selected, the first address increment signal Inc1 is transmitted to the clock input terminal of the address counter 120 as the clock signal for address counting. In this way, the address counter 120 performs address counting at the first frequency in the first configuration. When the second configuration is selected, the second address increment signal Inc2 is transmitted to the address counter 120 as the clock signal. In this way, the counting frequency of the address counter 120 switches to the second frequency, thereby lowering the transition speed of the address counter 120. This ensures that several jumps of the jump signal X are added during each address counting cycle, enabling sequential counting of the same address across a plurality of memory bank groups within each address counting cycle.

In this way, the entire address translation circuit achieves compatibility with both the first configuration and the second configuration of the memory.

An embodiment of the present disclosure further provides a memory 10, comprising the address translation circuit 100 and N memory bank groups 200 described in the foregoing embodiments. The memory will be described in detail below. It should be noted that the descriptions of the foregoing embodiments of the address translation circuit also apply to the embodiments of the memory. To avoid repetition, details of the content mentioned in the foregoing embodiments will not be elaborated below.

The memory comprises: the address translation circuit provided in the foregoing embodiment and N memory bank groups. The N memory bank groups perform ECS operations based on a first row address increment signal and a stop signal output by the address translation circuit.

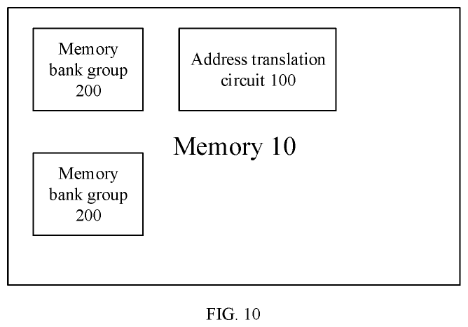

Referring to FIG. 10, a schematic structural diagram of a memory according to an embodiment of the present disclosure is shown. As shown in FIG. 10, the memory 10 includes: N memory bank groups 200 and an address translation circuit 100. The N memory bank groups 200 perform ECS operations based on the first row address increment signal Row_Inc1 and a stop signal EcsOut output by the address translation circuit 100. This ensures that the recorded address remains consistent with the actual address when two memory bank groups are merged, thus facilitating the recording of error address and enabling the memory 10 to execute ECS operations.

It should be understood that reference throughout this specification to “some embodiments”, “one embodiment” or “an embodiment” means that a particular feature, structure, or characteristic described in connection with the embodiment is included in at least one embodiment of the present disclosure. Therefore, the appearances of the phrases “in one embodiment” or “in an embodiment” in various places throughout this specification do not necessarily all refer to the same embodiment. Furthermore, these particular features, structures, or characteristics may be combined in any suitable manner in one or more embodiments. It should be understood that, in various embodiments of the present disclosure, the sequence numbers of the processes described above do not imply an order of execution, and the order of execution of the processes should be determined by their functions and inherent logic, and these sequence numbers should not constitute any limitation to the implementation process of the embodiments of the present disclosure. The serial numbers of the embodiments of the present disclosure described above are for the purpose of describing only and do not represent the superiority or inferiority of the embodiments.

It should be noted that the terms “includes,” “including,” “comprises,” “comprising,” or any other variants are intended to cover non-exclusive inclusion herein. Thus, a process, method, item, or apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The foregoing descriptions are only embodiments of the present disclosure, but the protection scope of the present disclosure is not limited thereto. Changes or substitutions that anyone skilled in the art can easily think of within the technical scope disclosed by the present disclosure shall all fall within the protection scope of the present disclosure. Therefore, the protection scope of the present disclosure shall be subject to the protection scope of the claims.

What is claimed is:

1. An address translation circuit, applicable to a memory, the memory comprising N memory bank groups, and the address translation circuit comprising:
a frequency division circuit, configured to receive a first address increment signal with a first frequency, process the first address increment signal, and output a second address increment signal with a second frequency as well as a jump signal with the second frequency, wherein the first address increment signal is used to indicate address incrementation when the memory is in a first configuration, and the second address increment signal is used to indicate address incrementation when the memory is in a second configuration; the jump signal is used to indicate an address jumping among the N memory bank groups; the first frequency is N times the second frequency, and N is a positive integer greater than 1;
an address counter, configured to receive the second address increment signal and output an address count signal; and
a row address increment circuit, coupled to the address counter and the frequency division circuit and configured to output a first row address increment signal when the address count signal indicates that column address counting has been finished, and the jump signal indicates a last memory bank group.

2. The address translation circuit according to claim 1, wherein the frequency division circuit comprises:
a first flip-flop, wherein a clock input terminal of the first flip-flop is configured to receive the first address increment signal, and an output terminal of the first flip-flop is connected to a data input terminal and outputs the jump signal; and
a first processing unit, wherein a first input terminal of the first processing unit is coupled to the output terminal of the first flip-flop, and a second input terminal of the first processing unit receives the first address increment signal; an output terminal of the first processing unit outputs the second address increment signal.

3. The address translation circuit according to claim 2, wherein the frequency division circuit further comprises: a first AND gate, wherein a first input terminal of the first AND gate receives a configuration signal that is used to indicate the second configuration, and a second input terminal of the first AND gate receives an initial reset signal; an output terminal of the first AND gate outputs a reset signal; a reset terminal of the first flip-flop receives the reset signal.

4. The address translation circuit according to claim 1, wherein the address counter comprises:
M counting units, wherein output terminals of the M counting units at all stages are respectively configured to output a count value of one bit of an address, and wherein M is an integer greater than 2;
M−1 second AND gates, wherein a first input terminal of each of the M−1 second AND gates is connected to an output terminal of one of the M counting units, and a second input terminal of each of the M−1 second AND gates is connected to an output terminal of a previous-stage counting unit or an output terminal of a preceding second AND gate; and
M−1 XOR gates, wherein a first input terminal of each of the M−1 XOR gates is connected to an output terminal of one of the M counting units or an output terminal of one of the M−1 second AND gates, and a second input terminal of each of the M−1 XOR gates is connected to an output terminal of a subsequent-stage counting unit.

5. The address translation circuit according to claim 4, wherein each of the M counting units comprises: a second flip-flop; the M counting units comprises: a first counting unit, a second counting unit, . . . , a (i+1)-th counting unit, . . . , wherein i is an integer greater than 1 and less than M;
wherein an output terminal of a second flip-flop in the first counting unit is connected to a data input terminal of the second flip-flop in the first counting unit;
a first input terminal of a first XOR gate is connected to the output terminal of the second flip-flop in the first counting unit, and a second input terminal of the first XOR gate is connected to an output terminal of a second flip-flop in the second counting unit; and
a first input terminal of an i-th XOR gate is connected to an output terminal of an (i−1)-th second AND gate, and a second input terminal of the i-th XOR gate is connected to an output terminal of the second flip-flop in the (i+1)-th counting unit.

6. The address translation circuit according to claim 5, wherein a first input terminal of a first second AND gate is connected to the output terminal of the second flip-flop in the second counting unit, and a second input terminal of the first second AND gate is connected to the output terminal of the second flip-flop in the first counting unit; and
a first input terminal of a j-th second AND gate is connected to an output terminal of a second flip-flop in the (j+1)-th counting unit, and a second input terminal of the j-th second AND gate is connected to an output terminal of a (j−1)-th second AND gate 122, wherein j is an integer greater than 1 and less than M.

7. The address translation circuit according to claim 5, wherein the address counter further comprises: a third AND gate, wherein
a first input terminal of the third AND gate is coupled to the frequency division circuit and configured to receive the jump signal, and a second input terminal of the third AND gate is connected to an output terminal of an (M−2)-th second AND gate; an output terminal of the third AND gate is configured to output a stop signal, the stop signal indicating that address counting has been finished.

8. The address translation circuit according to claim 7, wherein the address counter further comprises:
a first signal selector, wherein a first input terminal of the first signal selector is connected to an output terminal of an M-th second flip-flop in the address counter, and a second input terminal of the first signal selector is connected to an output terminal of the frequency division circuit and configured to receive the jump signal; a control terminal of the first signal selector is configured to receive a mode selection signal, and an output terminal of the first signal selector is connected to the first input terminal of the third AND gate; the mode selection signal is used to indicate whether the memory is in the first configuration or the second configuration.

9. The address translation circuit according to claim 1, wherein the row address increment circuit comprises:
a fourth AND gate, wherein a first input terminal of the fourth AND gate is connected to the address counter and configured to receive a second row address increment signal, and a second input terminal of the fourth AND gate is connected to an output terminal of the frequency division circuit and configured to receive the jump signal; an output terminal of the fourth AND gate outputs the first row address increment signal, wherein the second row address increment signal is used to indicate that the column address counting has been finished.

10. The address translation circuit according to claim 9, wherein the row address increment circuit further comprises:
a second signal selector, wherein a first input terminal of the second signal selector is connected to the address counter and configured to receive the second row address increment signal, and a second input terminal of the second signal selector is connected to the output terminal of the fourth AND gate; a signal selection terminal of the second signal selector is configured to receive a mode selection signal, wherein when the mode selection signal indicates that the memory is in the first configuration, the second signal selector outputs the second row address increment signal; when the mode selection signal indicates that the memory is in the second configuration, the second signal selector outputs the first row address increment signal.

11. The address translation circuit according to claim 1, further comprising:
a third signal selector, wherein a first input terminal of the third signal selector is configured to receive the first address increment signal, and a second input terminal of the third signal selector is connected to an output terminal of the frequency division circuit and configured to receive the second address increment signal; an output terminal of the third signal selector is connected to a clock input terminal of the address counter, and a signal selection terminal of the third signal selector is configured to receive a mode selection signal,
wherein when the mode selection signal indicates that the memory is in the first configuration, the third signal selector outputs the first address increment signal; when the mode selection signal indicates that the memory is in the second configuration, the third signal selector outputs the second address increment signal.

12. The address translation circuit according to claim 1, wherein a duty cycle of the jump signal is 1/N.

13. The address translation circuit according to claim 1, wherein the first configuration corresponds to an X8 mode of the memory, and the second configuration corresponds to an X16 mode of the memory.

14. The address translation circuit according to claim 2, wherein the first processing unit comprises a NOR gate that receives the first address increment signal and the jump signal and generates the second address increment signal.

15. A memory, comprising: N memory bank groups and the address translation circuit according to claim 1, wherein the N memory bank groups perform an ECS operation according to a first row address increment signal and a stop signal output by the address translation circuit.
